(19) United States
(12) Patent Application Publication
(10) Pub. No.: US 2026/0128567 A1
(43) Pub. Date: May 7, 2026

(54) TUNABLE LASERS AND THEIR SENSING APPLICATIONS

(71) Applicant: SENTEK INSTRUMENT, LLC, Blacksburg, VA (US)

(72) Inventors: Dyson BUITENKAMP, Blacksburg, VA (US); Logan THEIS, Blacksburg, VA (US)

(21) Appl. No.: 19/117,460

(22) PCT Filed: Oct. 6, 2023
(86) PCT No.: PCT/US2023/034617

§ 371 Date: Apr. 1, 2025

Related U.S. Application Data
(60) Provisional application No. 63/414,084, filed on Oct. 7, 2022.
(60) Provisional application No. 63/535,275, filed on Aug. 29, 2023.

(51) Int. Cl. H01S 5/062; H01S 5/026; H01S 5/06

(52) U.S. Cl. CPC H01S 5/06216; H01S 5/0265; H01S 5/0612

(57) ABSTRACT

The process of heating up a cavity with a diode laser or light beam source with a booster current pulse followed by application of a drive to the diode to produce a continuous wave (CW) over time while the cavity cools (spontaneously or otherwise), or by the application of pulses of current to produce pulsed waves of different wavelengths allows for fast tuning of wavelength laser or light emissions. These processes may be used with sensing fibers to sense a variety of different parameters including but not limited to temperature, strain, gas concentration, etc.

### CROSS-REFERENCE TO RELATED APPLICATIONS

This application claims priority to U.S. Ser. No. 63/414,084 filed Oct. 7, 2022, and to U.S. Ser. No. 63/535,275 filed Aug. 29, 2023, and the complete contents of both is herein incorporated by reference.

### BACKGROUND

Diode lasers have found a wide range of applications such as communication, sensing, metrology and light detection and ranging (LIDAR). Many of these applications may require the wavelength of laser emission to change in time.

One of the most common methods for wavelength tuning is to change the laser chip temperature by the control of the electric current injected into a thermo-electric cooler (TEC) to which the laser chip is mounted or attached. Given the relatively large thermal mass of the TEC, the wavelength tuning is usually in the order of multiple seconds for a few nanometer wavelength change.

Sakano et al. (U.S. Pat. No. 5,173,909) patented a method for improved thermal tuning speed by a special diode laser structure in which a temperature variable heater separated from an active layer (lasing region) by a distance less than the thickness of a compound semiconductor substrate. Because the heater is located very close to the active layer, the response time of temperature change is improved. This method requires a new laser diode structure. In addition to the laser driving circuit, a separate circuit for the laser heating is also necessary. All these will increase the laser cost.

Njegovee et al. (US 2014/0112361 A1) describes a method for fast diode laser tuning. In their method, a diode laser is driven by a very narrow pulse (well below 1 ms) that has a peak current in the order of multiple amperes. During the transitions of the current including the up and down slopes of the current pulse, the optical power varies but the laser wavelength changes at the same time. The varying optical power with the tuned wavelength is utilized for various purposes such as demodulation of Fabry-Perot interferometers.

Besides the methods above, another common method of wavelength tuning is the use of an external cavity. This method can offer a large wavelength tuning range sometimes at high speed. However, these types of lasers are often very expensive, typically thousands of dollars or more. Optical fiber tunable lasers are also available which could provide fast and wide wavelength tuning. However, unlike diode lasers where laser pulses can easily be generated by direct current modulation, fiber lasers are often not as easy in controlled pulse generation. In addition, similar to external cavity diode tunable lasers, these tunable fiber lasers are expensive and often susceptible to ambient vibration.

### SUMMARY

Aspects of the invention pertain to methods and apparatuses for the generation of fast wavelength tuning laser emissions which may be pulses or continuous wave (CW). The laser diode may be but is not limited to a distributed feedback (DFB) laser, a distributed Bragg reflector (DBR) laser, a Fabry-Perot (FP) laser, a vertical-cavity surface emitting laser (VCSEL), a quantum well or multi-quantum well laser, a quantum dot laser or any other laser whose emission wavelength can be tuned by laser chip temperature control. In one embodiment, a DFB laser is used as an example to explain the operation of a wavelength-tunable pulsed laser generation. Also, aspects of the invention may also be applied to other diodes that emit light.

Example diodes may include but are limited to light emitting diodes (LEDs) and superluminescent diodes (SLDs).

### DESCRIPTION OF THE DRAWINGS

FIG. 1a is a graph showing an initial booster pulse followed by a plurality of wavelength tunable pulses.

FIG. 1b is a graph showing an initial increase in laser temperature followed by a spontaneous cool down.

FIG. 2 is a schematic diagram of a device wherein the cavity can be heated up quickly using a booster pulse as shown in FIG. 1a.

FIG. 3 is a schematic diagram of a second embodiment of the invention where an optical modulator is used to chop a continuous wave laser into temporal pulses.

FIG. 4 is a graph showing the laser driving current and different wavelength pulses produced by an EAM voltage control.

FIG. 5 is a schematic showing a wavelength tunable laser being used in a sensing application with an optical fiber.

FIG. 6a is a graph showing an initial booster pulse followed by current for producing a continuous wave laser or light beam where the wavelength changes over time.

FIG. 6b is a graph for the device and methodology described in FIG. 6a showing an initial increase in laser temperature followed by a spontaneous cool down.

FIG. 7 is a schematic showing a different wavelength tunable laser being used in a sensing application with an optical fiber.

FIG. 8a-b are schematics showing a sensor for gas concentration measurements, and FIG. 8c is a graph representing a response for a gas concentration measurement.

FIG. 9 is a schematic of an exemplary optical frequency-domain reflector system based on the tunable laser.

### DETAILED DESCRIPTION

An embodiment of the invention pertains to a wavelength tunable pulsed laser, wherein the configuration is made to heat up the laser cavity of a diode laser rapidly by a booster current pulse and subsequently to let the laser temperature cool down spontaneously. The booster current rising edge may have any waveform including but not limited to step change, parabolic, linear or any other waveform that can produce a rapid temperature rise to the laser cavity. The falling edge of the booster current may or may not be a sudden drop to the current, which may or may not be the same as the current before the booster current is applied. The current before the booster current pulse may or may not be zero.

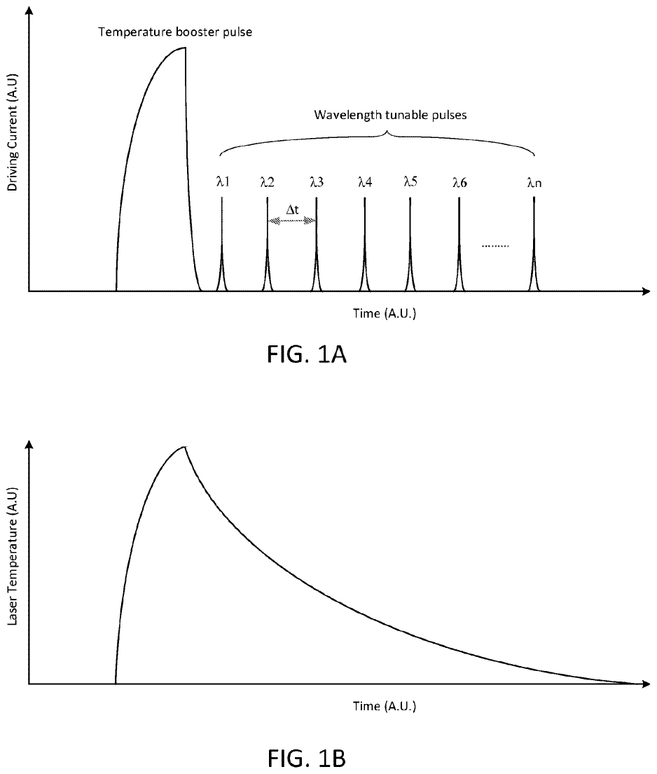

During the laser temperature spontaneous decay after the booster current pulse, the laser is then driven by successive current pulses. Owing to the laser wavelength dependence on temperature, these laser pulses have different wavelengths. The wavelength change from pulse to pulse may or may not be uniform in time. The successive driving current pulses may or may not have the same peak current and may or may not have the same temporal interval between adjacent pulses. The booster current pulse may be part of the laser diode driving current directly. FIG. 1a graphically explains the principle of the generation of wavelength-tunable laser pulses by a booster current followed by successive narrow driving pulses. The successive pulses time span may be shorter or longer than the booster pulse temporal duration. As shown by FIG. 1b, the temperature rise in time may be linear or non-linear.

In addition to the case where the booster current pulse is applied directly to the laser diode, a different structure may be designed. The light emitting laser diode is placed in the proximity of one or multiple elements that can produce a rapid temperature rise by a booster current pulse. The structure may be mounted or attached to a TEC and is designed such that the laser cavity temperature can not only rise but also fall rapidly after the booster current is reduced or disappears. This laser cavity temperature rapid increase and decrease may permit the cycle of wavelength-tuned pulse generation to repeat at a high frequency. These heating elements can produce a transient temperature change by the booster current pulse control. Example elements may include but are not limited to diodes or p-n junctions that may or may not be light emitting and components, layers or strips that exhibit electrical resistance and can consume part or the entirety of the injected booster electrical energy in the form of rapid temperature rise.

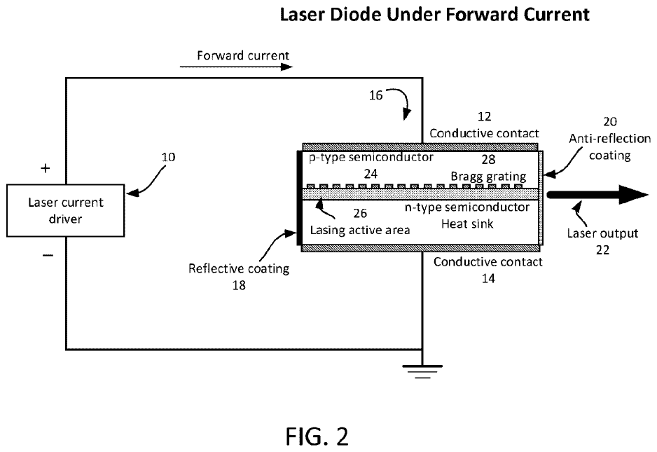

FIG. 2 shows a laser diode under forward current as discussed above in connection with FIGS. 1a-b. As shown in FIG. 2, a laser current driver 10 is connected to contacts 12 and 14 of the laser diode 16. The laser diode 16 may have a reflective coating 18 on one end and an antireflective coating 20 on the other end where the laser output 22 is directed. The laser diode 16 may have a p-type semiconductor portion 24 a n-type semiconductor portion 26, a heat sink (not shown with specificity) and a Bragg grating 28. As the laser current driver 10 drives the laser diode 16 with an initial booster current and then successive pulses, as described in conjunction with FIG. 1a, the cavity of the laser diode 16 is heated up and then with successive current pulses to produce laser beams 22 (or light beams in the case of an LED as opposed to a laser) of different wavelengths based on differences in a temperature of the cavity.

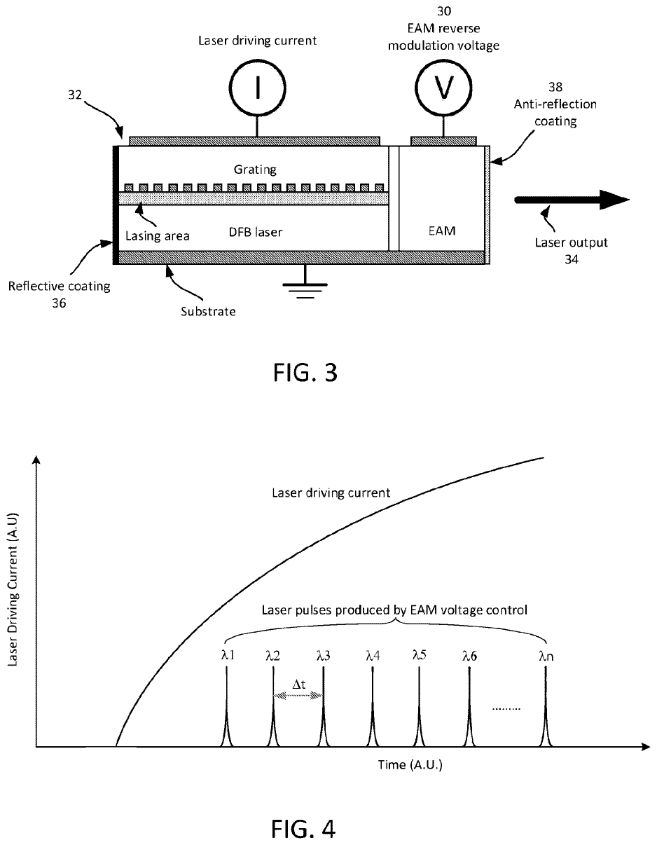

Another embodiment of the invention pertains to tuning the laser driving current while laser pulses are produced by a separate or integrated optical modulator. The optical modulator can be any device that can chop a continuous wave (CW) wavelength tuning laser beam into temporal pulses. The modulator may also chop long duration pulses into shorter duration pulses. The optical modulator may be but is not limited to an electro-absorption modulator (EAM) or any element or device that can convert a CW laser beam into temporal pulses. The EAM may be arranged immediately next to the laser cavity with an electrical isolation as shown in FIG. 3. Specifically, an optical modulator 30 such as an EAM is positioned adjacent to, contiguous with, or otherwise integrally formed with a laser diode 32 (or LED) such that the laser output 34 (or LED output) is modulated by the optical modulator 30. In this configuration, a reflective coating 36 can be positioned at the end of the laser diode 32 and the antireflective coating 38 can be placed on the end where the optical modulator 30 is located. The laser driving current 40 can be used to produce a continuous wave laser beam (or light beam), and the optical modulator 30 would effectively chop the beam into temporal pulses emitted as the output 34.

It is known that the emission wavelength of a DFB laser is dependent on the driving current. The driving current has mainly two effects on the diode. The first is a change in the charge carrier density in the laser cavity, which leads to a change in the index of refraction of the laser cavity material. This index change in turn shifts the laser wavelength. The second effect is thermal. Part of the current injected into the diode is converted into a temperature change, which varies both the refractive index and the dimensions of the laser cavity. The charge carrier density effect is dominant when the laser current is modulated very fast (<<1 ms) but the thermal effect becomes the main effect when the current change is slow.

By this embodiment of the present invention, the laser driving current is changed in time, which in turn changes not only the laser optical power, but also the laser wavelength. The time of the driving current tuning may or may not be greater than one millisecond (1ms). During the laser current tuning, the EAM reverse voltage is modulated to chop the wavelength tuned CW laser to produce laser pulses that have different wavelengths as graphically shown in FIG. 4.

In this embodiment the laser driving current may or may not keep changing in time during the EAM modulation for the generation of optical pulses. The laser current during the EAM controlled optical pulse generation may or may not be close to or reach the laser gain saturation where the output laser power may not change in time anymore.

A similar but distinct embodiment is to chop the optical pulses during the tuning/booster pulse using direct current modulation instead of a modulator such as an EAM as was described in the second embodiment. This could be viewed as a modulation to the booster current waveform. In the simplest version of this embodiment, the chopping is accomplished with a high extinction ratio such as where the laser driving current between short pulses is below the lasing threshold. To accomplish wavelength tuning, the peak current of each short pulse may or may not be increased with time. Therefore, the envelope of the short pulses forms the longer booster pulse which modulates the temperature, and the longer booster pulse is typically on the order of milliseconds and may or may not be greater than one millisecond (1 ms).

In this embodiment, the laser driving current between pulses may also be at a level above the lasing threshold. In this case, the extinction ratio of the pulses will suffer, but the thermal and therefore wavelength tuning range within the booster pulse may increase. A compromise between extinction ratio and tuning range may be found for the intended application.

The separate embodiments of this invention may be combined. For example, the booster pulse can be chopped by an EAM to obtain discrete pulses which increase in wavelength (such as was described as an example of the second embodiment), and as the temperature spontaneously decays direct current modulated pulses may be employed which decrease in wavelength (such as was described in the first embodiment). Another example of combining the embodiments is using low extinction ratio direct current modulated pulses with an envelope increasing in current over time on the order of milliseconds (such as was described as an example of the third embodiment), and as the temperature spontaneously decays direct current modulated pulses may be employed which decrease in wavelength (such as was described in the first embodiment).

The lasers that emit pulses with their wavelengths different from pulse to pulse described in the preceding embodiments of the present invention may be applied to fiber optic sensors. One of the sensing applications is to apply such a tunable pulsed laser to any of the systems as described in U.S. Pat. No. 9,677,957 B2, an issued U.S. patent with Sentek Instrument LLC as the assignee, which is herein incorporated by reference.

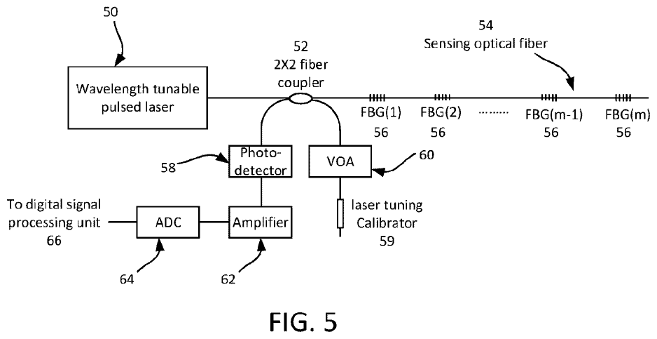

FIG. 5 presents one example system of such applications. In FIG. 5, a wavelength tunable pulsed laser 50 is directed through a coupler 52 to a sensing optical fiber 54. During one wavelength scanning cycle, the laser 50 sends successive optical pulses of differing center wavelengths into the sensing optical fiber 54 that has a single or plural fiber Bragg gratings (FBGs) 56 or Fabry-Perot interferometers through a 2×2 fiber coupler 52. In FIG. 5 an FBG array is used as an example of the sensing fiber 54 to describe the operation of a sensing or distributed sensing system. Each FBG 56 has a narrow reflection spectrum and these FBGs may or may not have identical spectra. Also, these gratings may or may not be weak reflecting FBGs. A weak grating may be defined to have a power reflectance of no more than 10%.

The temporal interval between adjacent input pulses from the laser 50 may be equal to or greater than the time of flight of light between the first grating, FBG(1), and the last grating, FBG(m), in the sensing fiber 54. Such an arrangement will make no more than one input laser pulse present in the sensing region of the sensing fiber 54 at any given time. When the wavelength of an input laser pulse falls into the reflection spectrum of a grating 56, part of the pulse energy is reflected toward the photodetector 58. As a result, an input laser pulse may produce a sequence of pulses returned from the serial gratings 56 in the sensing fiber 54. The strength of the reflection from a given grating varies as the laser wavelength is tuned from input pulse to pulse. The reflection spectrum of the grating can be constructed from the strengths of the pulses reflected from the grating. Thus, the reflection spectrum of each grating in the sensing fiber can be obtained. Since grating spectrum characteristics such as the peak or Bragg wavelength depends on different parameters such as temperature or strain, distributed sensing of these parameters can be achieved.

For accurate grating spectrum measurement, the laser wavelength tuning may or may not be tracked or calibrated in real time by a laser tuning calibrator 59. A variable optical attenuator 60 (VOA) may or may not be used to control the optical power reflected from the laser tuning calibrator 59 back into the photodetector 58. The function of the laser tuning calibrator 59 is to generate information about the wavelengths of the successive laser pulses so the laser wavelength tuning can be made repeatable for different laser tuning cycles by digital signal processing. The laser tuning calibrator 59 may include but is not limited to a Fabry-Perot interferometer, a Michelson interferometer, a Mach-Zehnder interferometer, a gas cell that offers a stable absorption spectrum, a random-FBG with known optical spectrum characteristics, a series of FBGs with differing center wavelengths, or any other device that can provide accurate wavelength information.

The optical signal from the laser tuning calibrator 59 may be detected by the same photodetector 58 and is separated in time from the reflections from the sensing fiber 54. The signal from the laser tuning calibrator 59 may also be detected by a separate photodetector (not shown).

Output from the photodetector 58 may be amplified 62, converted to digital signals by analog to digital converter 64, and processed by a digital processing unit 66.

In addition to temperature or strain, the system in FIG. 5 may also measure numerous other physical and chemical quantities when a specially designed optical fiber is used. The special fiber may include but is not limited to the example given in FIGS. 3-4 of U.S. Pat. No. 10,408,995 B1, the contents of which is herein incorporated by reference.

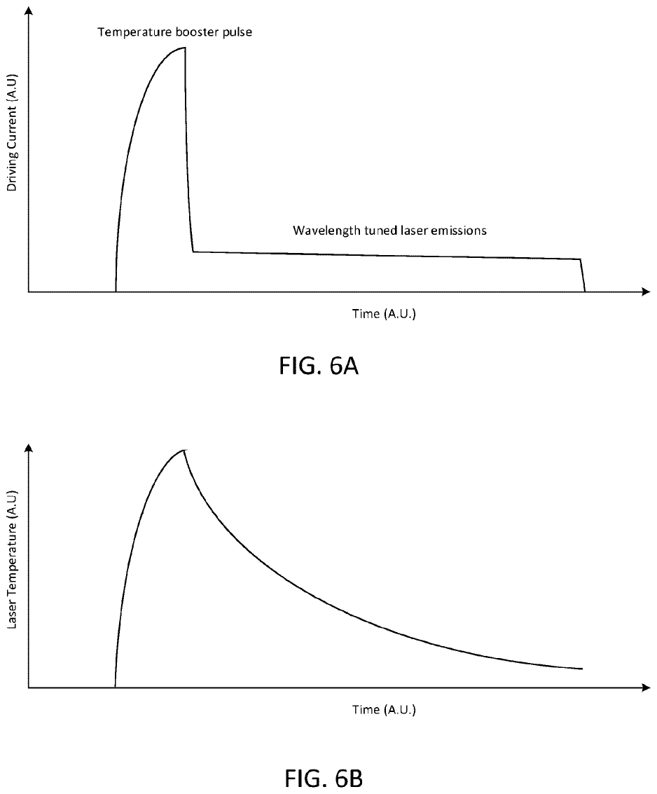

In addition to the wavelength tuning from pulse to pulse as described above, another embodiment of the present invention is to generate continuous wave (CW) wavelength tunable laser emissions as graphically explained in FIGS. 6a and 6b. Similar to FIG. 1a, FIG. 6a shows that after the large booster current which heats up the laser light emission area rapidly, the laser temperature begins to decline in time, then in contrast to FIG. 1a, FIG. 6a shows the laser driving current is then switched to another continuous current which may or may be smaller or much smaller than the booster current. The laser temperature decay may or may not be dominantly affected by the disappearance of the booster current. Consequently, the wavelength of CW laser emission would change in time. The booster current followed by the CW laser emission may be repeated at a certain frequency.

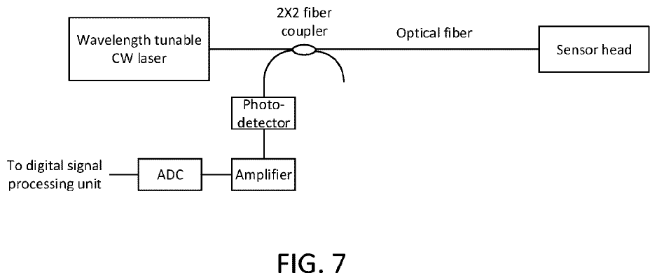

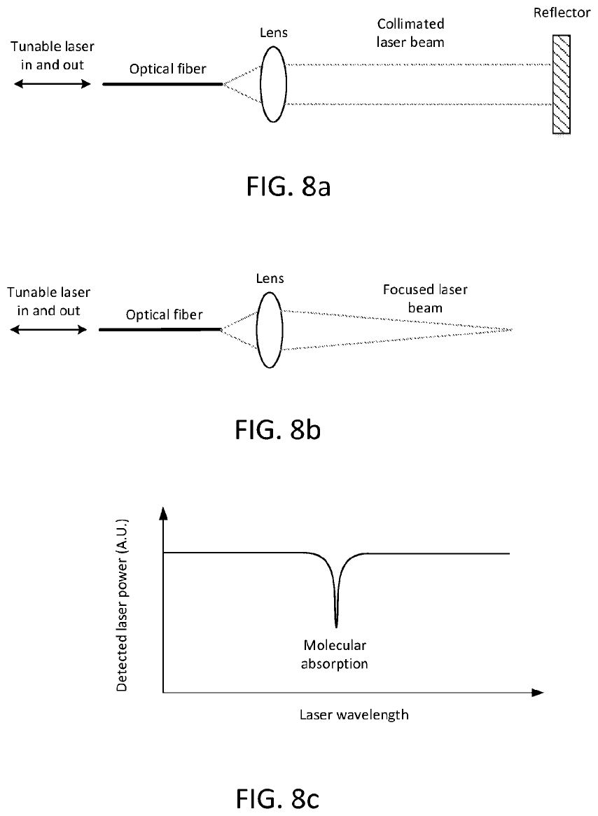

This wavelength tunable CW laser described in conjunction with FIG. 6a may have many applications. One of them is the interrogation of a sensor that can be measured by a tunable laser as illustrated in FIG. 7, which is similar to the schematic depicted in FIG. 5. The sensor may be but is not limited to any sensor design that can be interrogated by a wavelength tunable laser. One example is an FBG for measurement of temperature, strain, vibration, hydrogen or magnetic fields. Two other examples are given in FIG. 8a and FIG. 8b for gas concentration measurements. When gas molecules that have signature absorption at a certain wavelength present in the laser path as in FIG. 8a or at the laser focus in FIG. 8b, the detected laser power would exhibit an absorption dip in the light spectrum as illustrated in FIG. 8c. By the absorption wavelength position and the absorption dip depth, the presence and concentration of the targeted gas can be detected and measured. These sensors may also permit the simultaneous detection of multiple gases that have different absorption lines within the laser tuning range. The tunable laser described in the present invention may also be applied to many other sensing schemes such as an optical frequency-domain reflector (OFDR).

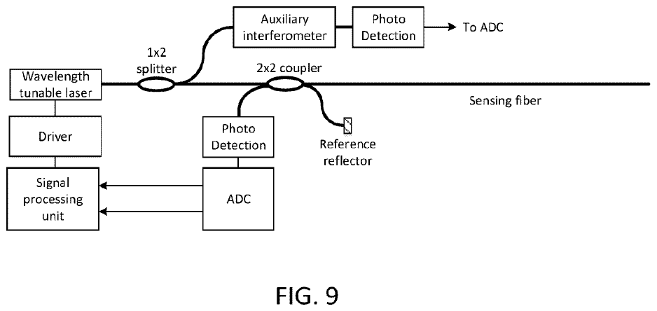

FIG. 9 shows one example OFDR system based on the tunable laser. The laser output is tapped in part by a 1×2 splitter into an auxiliary interferometer such as a Mach-Zehnder or Michelson interferometer for the laser tuning linearization. The rest of the laser is split by a 2×2 coupler into a sensing fiber and a reference reflector. The sensing fiber may or may not have additional microstructures such as serial FBGs in the fiber core or cladding or both. By the processing of the data from the auxiliary interferometer and the interference between the reflections from the reference reflector and different locations of the sensing fiber, changes in the optical path distance (ODP) of each sensing fiber segment can be determined. These changes may be related to any quantity such as temperature or strain that can change the fiber OPD.

The tunable laser in FIG. 9 and may be applied to any other OFDR design. Additionally, the embodiments described above in connection with the continuous wave wavelength tunable laser may be combined with the embodiments described in connection with the wavelength tunable pulsed laser. As an example, when measuring the absorption dip wavelength position and depth, the tunable pulsed operation could be used as a sort of coarse search for different absorption dips in an unknown gas's absorption profile such as when the absorption profile may be complicated and contain multiple dips. In this example, once a profile is determined and a dip is selected for analysis, the interrogator may switch to CW operation for a higher resolution measurement that takes advantage of the continuous tuning.

Both the CW and pulsed tunable laser embodiments of this invention may have adjustable current profiles, TEC-based biasing, and changes to any modulator which may be present in the embodiment, occurring during operation of a sensing system in an automated or manual manner. For example, the center wavelength of the tuning may change with time by changing a DFB laser's TEC bias point in order to cover a wider tuning range, potentially but not necessarily at the expense of measurand update rate. A more specific example may be checking several absorption dips during a gas absorption measurement by changing the TEC bias point, or by having multiple selectable pulse repetition rates to change the resolution or update rate of the sensing system for user preference, changes in signal quality, or as a system initialization procedure.

1. A method for tuning a laser or light source, comprising:
initially heating a cavity of a diode laser or light source by providing a booster current pulse to the cavity; and then
during temperature decay after the booster current pulse,
i) driving the diode laser or light source with successive current pulses to produce laser beams or light beams of different wavelengths based on differences in a temperature of the cavity, or
ii) driving the diode laser or light source with a continuous current for a selected time period to produce laser beams or light beams of different wavelengths based on differences in a temperature of the cavity over the time period.

2. The method of claim 1 wherein i) is performed and wherein a wavelength change from pulse to pulse of the laser beams or light beams is uniform.

3. The method of claim 1 wherein i) is performed and wherein a wavelength change from pulse to pulse of the laser beams or light beams is non-uniform.

4. The method of claim 1 wherein the diode laser or light source is a diode laser selected from the group consisting of a distributed feedback laser, a distributed Bragg reflector, a Fabry-Perot laser, a vertical cavity surface emitting laser, a quantum well laser, a multi quantum well laser, and a quantum dot laser.

5. The method of claim 1 wherein the diode laser or light source is a diode light source selected from the group consisting of a light emitting diode and a superluminescent diode.

6. The method of claim 1 wherein ii) is performed.

7. A method for providing a tuned pulsed laser or light beam, comprising:
producing a continuous wave laser or light beam using a driving current; and
chopping the continuous wave laser or light beam into temporal pulses using an optical modulator that is positioned to receive the continuous wave laser or light beam, wherein the temporal pulses have different wavelengths.

8. The method of claim 7 wherein the driving current is varied with time during chopping.

9. The method of claim 7 wherein the driving current is not varied with time during chopping.

10. The method of claim 7 wherein, during the producing step, the driving current is modulated at a speed where a charge carrier density effect is dominant.

11. A device for providing a tuned pulsed laser beam, comprising:
a continuous wave laser beam source;
a source of laser driving current connected to the continuous wave laser beam source; and
an optical modulator positioned to chop a continuous wave laser produced by the continuous wave laser beam source into temporal pulses having different wavelengths.

12. The device of claim 11 wherein the optical modulator is integral with the continuous wave laser beam source.

13. The device of claim 11 wherein the optical modulator is an electroabsorption modulator.

14. A sensor, comprising
a source of a tuned pulsed laser or light beam;
a sensing fiber positioned to receive a pulsed laser or light beam from said source of the tuned pulsed laser or light beam; and
a detector for detecting the pulsed laser or light beam after passing through at least a portion of the sensing fiber,
wherein the source of the tuned pulsed laser or light beam comprises
i) a cavity
a diode laser or light source positioned in the cavity,
wherein the cavity is heatable by applying a booster current pulse to the cavity, followed by a temperature decay, and
wherein the diode laser or light source is drivable by with successive current pulses to produce laser beams or light beams of different wavelengths based on differences in a temperature of the cavity, or wherein the diode laser or light source is drivable with a continuous current for a selected time period to produce laser beams or light beams of different wavelengths based on differences in a temperature of the cavity over the time period, or
ii) a continuous wave laser beam source,
a source of laser driving current connected to the continuous wave laser beam source, and
an optical modulator positioned to chop a continuous wave laser produced by the continuous wave laser beam source into temporal pulses having different wavelengths.

15. The sensor of claim 14 wherein the sensing fiber has one or more Bragg gratings or Fabry Perot interferometers positioned in or connected to the sensing fiber.

16. The sensor of claim 15 wherein the sensing fiber has a plurality of spaced apart Bragg gratings or Fabry Perot interferometers positioned in or connected to the sensing fiber, wherein different Bragg gratings or different Fabry Perot interferometers in the plurality are responsive to different wavelengths of the pulsed laser or light beam.

17. The sensor of claim 14 wherein a reflectivity of the Bragg gratings or Fabry Perot interferometers changes depending on strain or temperature operating on the sensing fiber.
